(19) United States
(12) Patent Application Publication
(10) Pub. No.: US 2025/0179637 A1
(43) Pub. Date: Jun. 5, 2025

(54) SHOWERHEAD FOR SUBSTRATE PROCESSING SYSTEMS

(71) Applicant: LAM RESEARCH CORPORATION, Fremont, CA (US)

(72) Inventors: Simon CHAN, Campbell, CA (US); Ravi PARMAR, San Jose, CA (US); Arun Kumar HOSUR SHIVALINGE GOWDA, Bangalore (IN); Leonard KHO, San Francisco, CA (US); Zhongbo YAN, Newark, CA (US); Vishaisagar KITTUR, Bangalore (IN); Ashwin Agathya BOOCHAKRAVARTHY, Fremont, CA (US); Xiaolan BA, Fremont, CA (US); Lav KAUSHIK, Bangalore (IN); Tae Won SUH, Redwood City, CA (US)

(21) Appl. No.: 18/843,586

(22) PCT Filed: Mar. 9, 2023
(86) PCT No.: PCT/US2023/014877

§ 371 Date: Sep. 3, 2024

Related U.S. Application Data
(60) Provisional application No. 63/320,015, filed on Mar. 15, 2022.

(51) Int. Cl. C23C 16/455; C23C 16/52; H01J 37/32

(52) U.S. Cl. CPC C23C 16/45565; C23C 16/52; H01J 37/32449; H01J 2237/332

(57) ABSTRACT

A dual-plenum showerhead for a substrate processing system comprises a base portion and a backplate. The base portion comprises a first surface facing a substrate, a second surface opposite the first surface, and a sidewall extending between the first surface and the second surface. The first and second surfaces are flat. The first and second surfaces and the sidewall define a first plenum. The backplate comprises a shaped surface extending from a center portion of the backplate to a periphery of the backplate. The shaped surface comprises a plurality of portions. At least one of the portions is parallel to the base portion. At least one of the portions slopes towards the base portion. The periphery of the backplate is attached to the second surface of the base portion defining a second plenum.

### CROSS-REFERENCE TO RELATED APPLICATIONS

This application claims the benefit of U.S. Provisional Application No. 63/320,015, filed on Mar. 15, 2022. The entire disclosure of the application referenced above is incorporated herein by reference.

### FIELD

The present disclosure relates generally to substrate processing systems and more particularly to showerheads for the substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing tool typically comprises a plurality of stations in which to perform deposition, etching, and other treatments on substrates such as semiconductor wafers. Examples of processes that may be performed on a substrate comprise a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate comprise etching (e.g., chemical etching, plasma etching, reactive ion etching, etc.) and cleaning processes.

During processing, a substrate is arranged on a substrate support such as a pedestal in a station. During deposition, gas mixtures comprising one or more precursors are introduced into the station, and plasma may be optionally struck to activate chemical reactions. During etching, gas mixtures comprising etch gases are introduced into the station, and plasma may be optionally struck to activate chemical reactions. A computer-controlled robot typically transfers substrates from one station to another in a sequence in which the substrates are to be processed.

In ALD, a gaseous chemical process sequentially deposited a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material. Thermal ALD (T-ALD) is carried out in a heated station. The station is maintained at a sub-atmospheric pressure using a vacuum pump and a controlled flow of an inert gas. The substrate to be coated with an ALD film is placed in the station and is allowed to equilibrate with the temperature of the station before starting the ALD process.

### SUMMARY

A dual-plenum showerhead for a substrate processing system comprises a base portion and a backplate. The base portion comprises a first surface facing a substrate, a second surface opposite the first surface, and a sidewall extending between the first surface and the second surface. The first and second surfaces are flat. The first and second surfaces and the sidewall define a first plenum. The backplate comprises a shaped surface extending from a center portion of the backplate to a periphery of the backplate. The shaped surface comprises a plurality of portions. At least one of the portions is parallel to the base portion. At least one of the portions slopes towards the base portion. The periphery of the backplate is attached to the second surface of the base portion defining a second plenum.

In additional features, the base portion and the backplate are cylindrical. The dual-plenum showerhead further comprises a plate disposed between the shaped surface and the second surface of the base portion. The plate is of a smaller diameter than the base portion and comprising a plurality of through holes.

In additional features, dimensions of the through holes increase along a radius of the plate.

In additional features, the through holes are arranged on the plate in concentric circles.

In additional features, diameters of the through holes increase with radii of the circles.

In additional features, a thickness of the plate is less than a distance between the second surface of the base portion and the center portion of the backplate.

In additional features, a thickness of the plate is less than a distance between the second surface of the base portion and at least one of the portions of the shaped surface that is parallel to the base portion and that lies within a radius of the plate.

In additional features, a thickness of the plate is less than a distance between the second surface of the base portion and at least one of the portions of the shaped surface that slopes towards the base portion and that lies within a radius of the plate.

In additional features, a thickness of the plate is greater than a distance between the second surface of the base portion and at least one of the portions of the shaped surface that is parallel to the base portion and that lies outside a radius of the plate.

In additional features, a thickness of the plate is greater than a distance between the second surface of the base portion and at least one of the portions of the shaped surface that slopes towards the base portion and that lies outside a radius of the plate.

In additional features, the plate tapers near an outer diameter of the plate.

In additional features, the plate is rounded near an outer diameter edge of the plate.

In additional features, the base portion comprises a first set of through holes extending from the first surface to the first plenum and a second set of through holes extending from the first surface to the second surface. The first plenum and the first set of through holes are not in fluid communication with the second plenum and the second set of through holes. The second plenum, the second set of through holes, and the through holes in the plate are in fluid communication with each other.

In additional features, the dual-plenum showerhead further comprises a stem portion attached to the backplate and an adapter attached to the stem portion. The adapter comprises a cooling channel disposed in a portion of the adapter to circulate a coolant through the cooling channel.

In additional features, the stem portion and the adapter comprise passages that are separately connected to the first and second plenums.

In additional features, the dual-plenum showerhead further comprises a plate disposed between the shaped surface and the second surface of the base portion. The plate is of a smaller diameter than the base portion and comprises a plurality of through holes. A first one of the passages is connected to the second plenum through the center portion of the backplate. A second one of the passages passes through the center portion of the backplate and a center region of the plate and is connected to the first plenum.

In additional features, the first and second one of the passages are coaxial.

In additional features, the dual-plenum showerhead further comprises a heater disposed in the backplate.

In additional features, the backplate comprises a flat surface opposite the shaped surface, a second sidewall that extends from the periphery of the backplate towards the flat surface, and a heater disposed in a groove in the second sidewall at a distal end of the second sidewall.

In additional features, the base portion comprises bores cross-drilled laterally through the base portion. A first set of through holes extend from the first surface through bored regions of the base portion to the first plenum. A second set of through holes extend from the first surface, through non-bored regions of the base portion, and through the second surface to the second plenum.

In additional features, the dual-plenum showerhead further comprises a ring attached to sidewall of the base portion enclosing the bores.

In additional features, the first and second sets of through holes comprise conical ends at the first surface of the base portion.

In additional features, the first set of though holes are smaller in length and diameter than the second set of through holes.

In additional features, the first and second sets of holes comprise a cylindrical portion and a conical portion extending from the cylindrical portion. The cylindrical portions of the first and second sets of through holes extend to the first and second plenums, respectively. The conical portions of the first and second set of through holes extend to the first surface of the base portion.

In additional features, the cylindrical and conical portions of the first set of through holes are smaller in length and diameter than the cylindrical and conical portions of the second set of through holes, respectively.

In additional features, the cylindrical portions of the first set of through holes are smaller in length and diameter than the cylindrical portions of the second set of through holes. The conical portions of the first set of through holes are smaller in length and diameter than the conical portions of the second set of through holes.

In additional features, the conical portions of the first set of through holes extend at a first angle relative to an axis parallel to a length of the cylindrical portions of the first set of through holes. The conical portions of the second set of through holes extend at a second angle relative to an axis parallel to a length of the cylindrical portions of the second set of through holes.

In additional features, the first and second angles are equal.

In additional features, a system comprises the showerhead, a first gas source, a second gas source, and a controller. The first gas source is configured to supply a first gas to the first plenum. The second gas source is configured to supply a second gas to the second plenum. The controller is configured to control a flow rate of the first gas at a flow rate selected to reduce jetting of the second gas through the second set of through holes and to reduce the second gas from diffusing into the first plenum via the first set of through holes.

In additional features, a system comprises the showerhead, a first gas source, a second gas source, and a controller. The first gas source configured to supply a first gas to the first plenum. The second gas source configured to supply a second gas to the second plenum. The controller is configured to control a flow rate of the second gas at a flow rate selected to reduce jetting of the first gas through the first set of through holes and to reduce the first gas from diffusing into the second plenum via the second set of through holes.

In additional features, a total length of the first set of through holes is in a range of 0.15-0.35 inch. A total length of the second set of through holes is in a range of 0.5-0.7 inch.

In additional features, a diameter of the cylindrical portions of the first set of through holes is in a range of 0.014-0.018 inch. A diameter of the cylindrical portions of the second set of through holes is in a range of 0.029-0.039 inch.

In additional features, the conical portions of the first and second sets of through holes extend at an angle in a range of 30-60 degrees relative to an axis parallel to lengths of the cylindrical portions of the first and second sets of through holes.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 schematically shows an example of a substrate processing tool comprising multiple stations for processing substrates;

FIG. 2 shows an example of a substrate processing system comprising a station configured to process a substrate;

FIG. 3 shows a cross-sectional view of a dual plenum showerhead according to the present disclosure;

FIGS. 4A and 4B show an example of a profile of an upper plenum formed in a backplate of the dual plenum showerhead of FIG. 3 in further detail;

FIG. 5 shows an example of a baffle plate used in the upper plenum of the dual plenum showerhead of FIG. 3 in further detail;

FIGS. 6A and 6B show a heater of the dual plenum showerhead of FIG. 3 in further detail;

FIGS. 7A-7F show an example of an adapter attached to a stem portion of the dual plenum showerhead of FIG. 3 in further detail;

FIGS. 8A-8C show a first example of a lower plenum formed in a base portion of the dual plenum showerhead of FIG. 3 in further detail;

FIGS. 9A-9C show a second example of the lower plenum formed in the base portion of the dual plenum showerhead of FIG. 3 in further detail;

FIG. 10 shows through holes formed on an upper surface of the base portion of the dual plenum showerhead of FIG. 3;

FIGS. 11 and 12 show examples of patterns of through holes formed on a lower, substrate-facing surface of the base portion of the dual plenum showerhead of FIG. 3;

FIG. 13 shows a cross-sectional view of a second dual plenum showerhead according to the present disclosure;

FIG. 14 shows a bottom view of the second dual plenum showerhead;

FIG. 15 shows an example of a through hole of the upper plenum; and

FIG. 16 shows an example of a through holes of the lower plenum.

In the drawings, reference numbers may be reused to identify similar and/or identical elements.

### DETAILED DESCRIPTION

Before describing the problems solved by the present disclosure, a dual plenum showerhead is briefly described. Some substrates are processed by supplying different process gases using dual plenum showerheads. For example, a dual plenum showerhead (hereinafter the showerhead) comprises a base portion that is attached to a backplate. A first plenum is defined in the base portion by diametrically cross-drilling bores through the base portion. The cross-drilling forms vertical pillars in the base portion. The pillars extend between lower and upper surfaces of the base portion. The lower surface of the base portion faces a substrate. The upper surface of the base portion is attached to a bottom of the backplate. Spaces between the pillars define the first plenum in the base portion. A first plurality of through holes is drilled vertically from the lower surface of the base portion through the spaces between the pillars but not through the upper surface of the base portion. The first plurality of through holes is in fluid communication with the first plenum. A second plurality of through holes is drilled vertically from the lower surface of the base portion through the pillars and the upper surface of the base portion.

A second plenum is defined in the backplate by removing material from the bottom of the backplate. When the base portion is attached to the backplate, the upper surface of the base portion and the bottom of the backplate define the second plenum. The second plurality of through holes is in fluid communication with the second plenum. The second plenum and the second plurality of through holes are not in fluid communication with the first plenum and the first plurality of through holes. For convenience, the first plenum in the base portion may be called a lower plenum, and the second plenum in the backplate may be called an upper plenum.

The showerhead comprises a stem portion that is attached to the backplate. The stem portion comprises a first passage and a second passage that are bored through the stem portion. The first passage is in fluid communication with the first plenum and the first plurality of through holes. The second passage is in fluid communication with the second plenum and the second plurality of through holes. The first and second gas passages are disjoint (i.e., separate) and are not in fluid communication with each other. Accordingly, process gases can be supplied separately through the first and second passages to the first and second plenums, respectively. Specifically, a first process gas can be supplied through the first passage to the first plenum and through the first plurality of through holes to the substrate. A second process gas can be supplied through the second passage to the second plenum and through the second plurality of through holes to the substrate.

Typically, the upper plenum is cylindrical and extends diametrically across the bottom of the backplate. A volume of the upper plenum determines various aspects of substrate processing. For example, the volume of the upper plenum determines purge time, process uniformity (e.g., % nonuniformity in film resistance), and film quality (e.g., halogen content in the film). The present disclosure improves these aspects by reducing the volume of the upper plenum. Specifically, the present disclosure reduces the volume of the upper plenum by profiling (shaping) the upper plenum as described below in detail.

Additionally, the process gas supplied through the second plenum tends to flow more through the center region of the second plenum than through the peripheral region of the second plenum. The present disclosure provides a baffle plate that is disposed in the center region of the second plenum. The baffle plate is designed to divert the process gases and to uniformly distribute the process gas from the center to the edge of the baffle plate. The uniform distribution is achieved by drilling holes through the baffle plate with diameters increasing from the center to the edge of the baffle plate.

Further, the showerhead is heated during substrate processing. In addition, the showerhead is in close proximity to a heated pedestal during substrate processing. As a result, the showerhead reaches high temperatures (e.g., of several hundred degrees) during substrate processing. The heat from the showerhead is transported through the stem to a manifold used to supply process gases to the showerhead. The present disclosure provides an adapter attached to the stem of the showerhead. The adapter is cooled as described below in detail. The adapter reduces the amount of heat transferred from the showerhead to the manifold.

In addition, the amount of process gas used to process substrates can be reduced by reducing the gap between the showerhead and the substrate. However, when the gap between the showerhead and the substrate is reduced, it is desirable to optimize the geometries of the through holes of the dual plenums and the flow rate of the inert gas supplied through the lower plenum to prevent jetting (pronounced or excessive localized deposition or etching) on the substrate and to prevent the process gas supplied through the upper plenum from diffusing or flowing back into the showerhead. These and other features of the present disclosure are described below in detail.

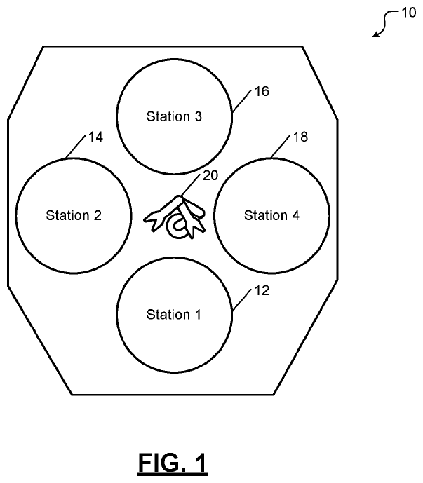

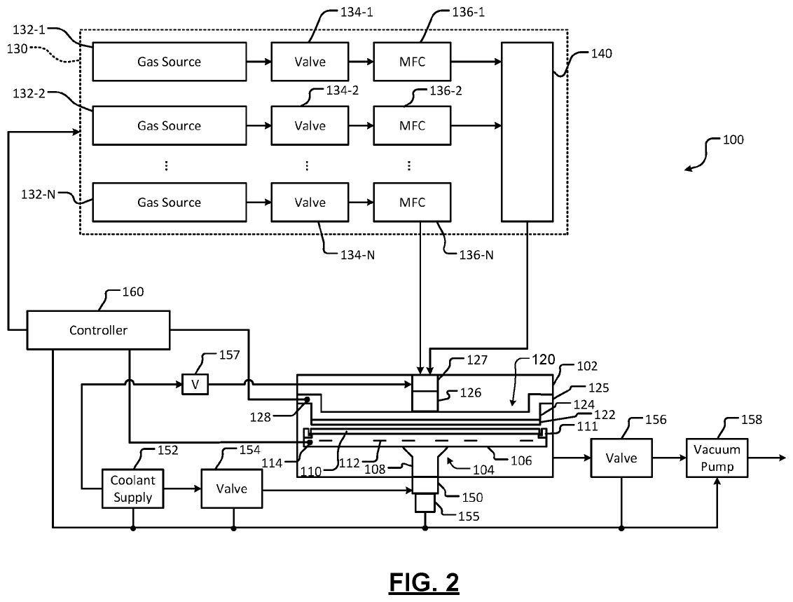

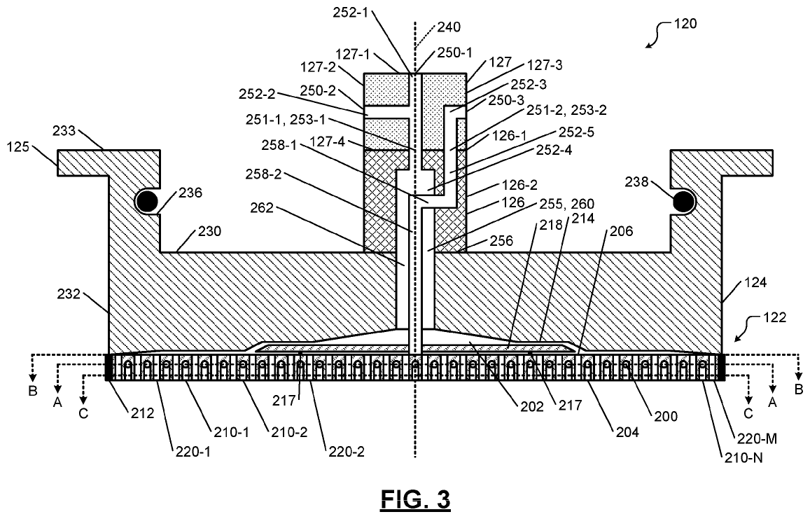

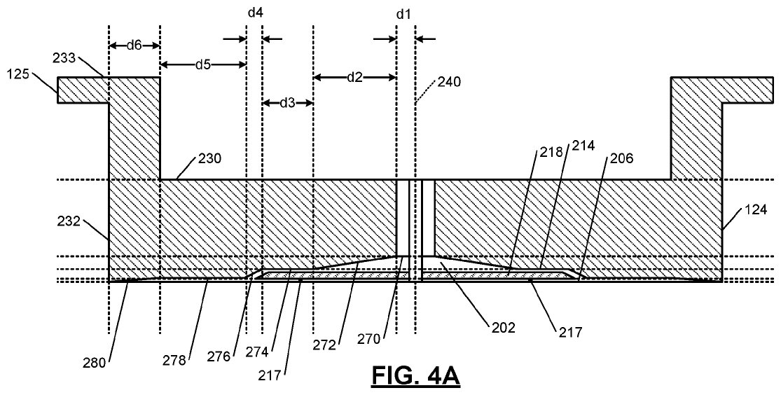

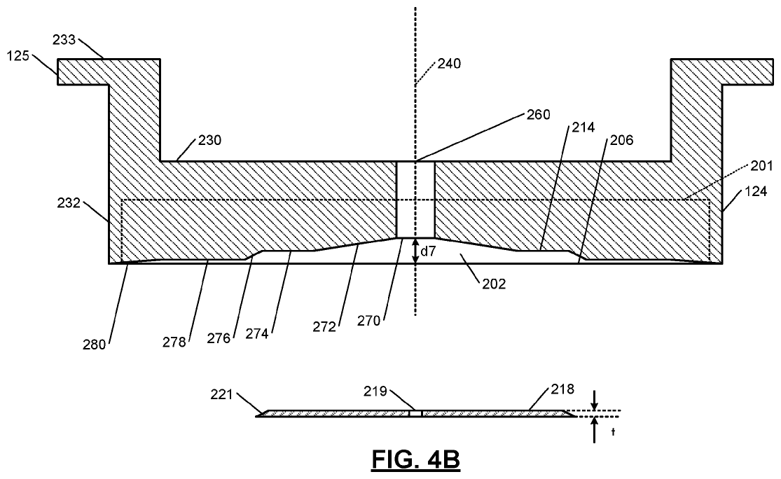

The present disclosure is organized as follows. Initially, to provide context, an example of a substrate processing tool comprising multiple stations is shown and described with reference to FIG. 1. An example of a substrate processing system comprising a station configured to process a substrate using the dual plenum showerhead of the present disclosure is shown and described with reference to FIG. 2. A cross-sectional view of the dual plenum showerhead according to the present disclosure is shown and described with reference to FIG. 3. An example of a profile of the upper plenum of the dual plenum showerhead according to the present disclosure is shown and described in further detail with reference to FIGS. 4A and 4B. An example of a baffle plate used in the upper plenum of the dual plenum showerhead according to the present disclosure is shown and described in further detail with reference to FIG. 5.

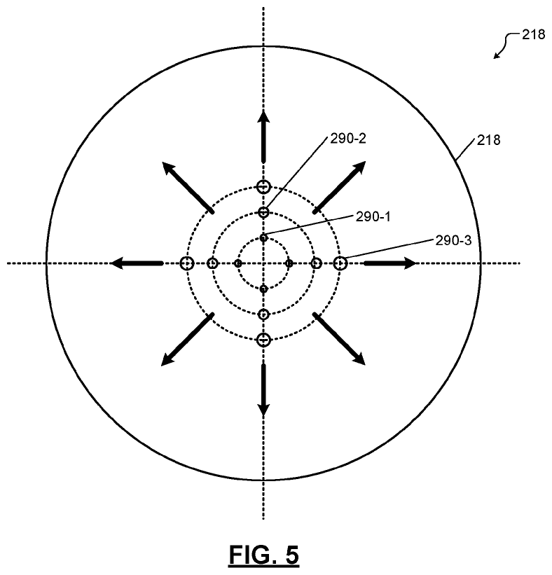

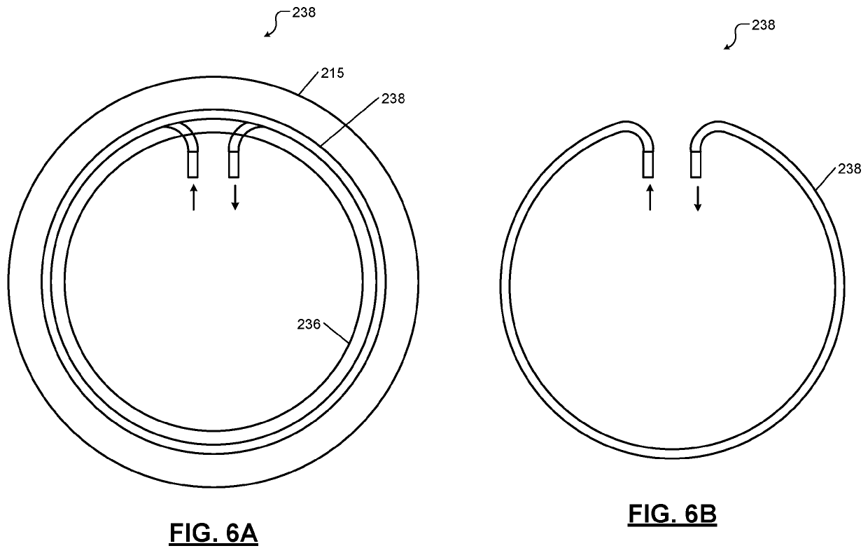

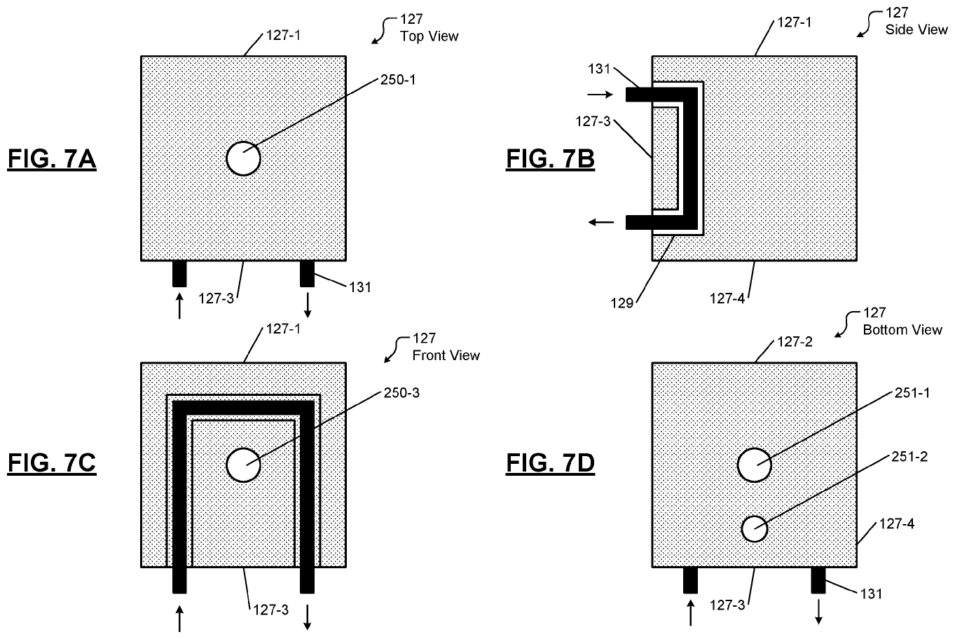

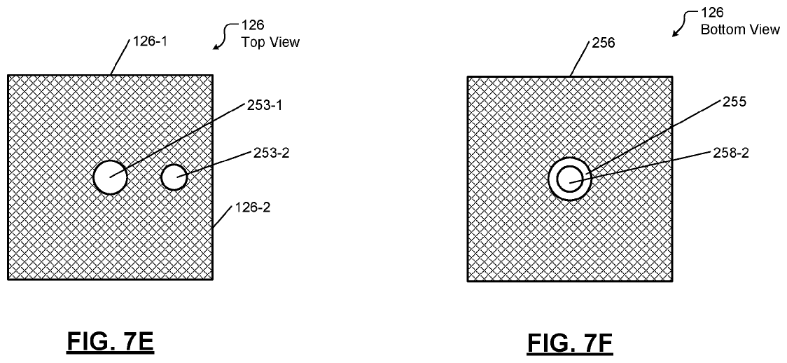

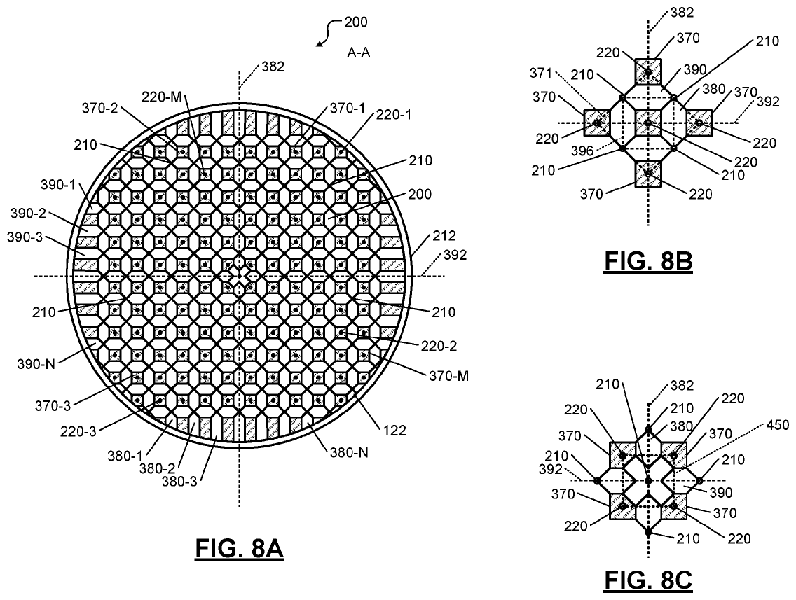

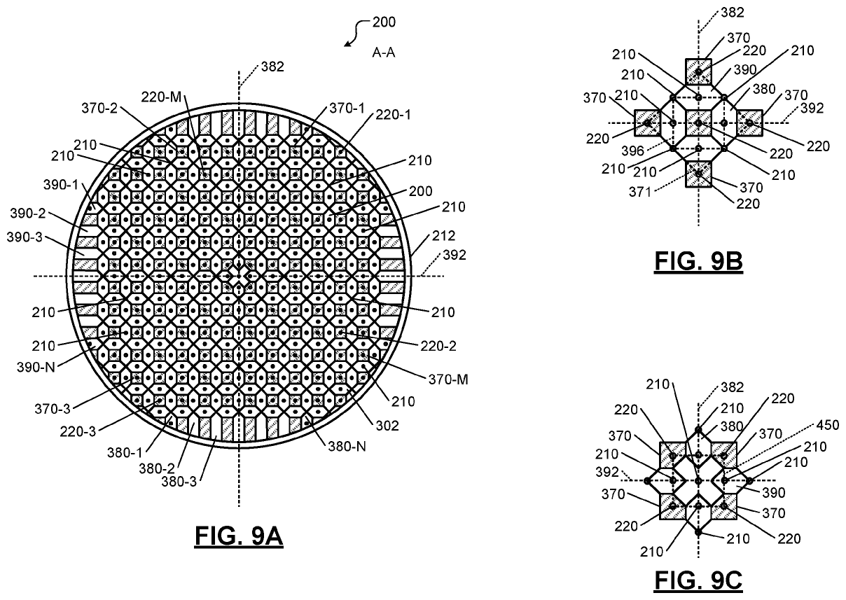

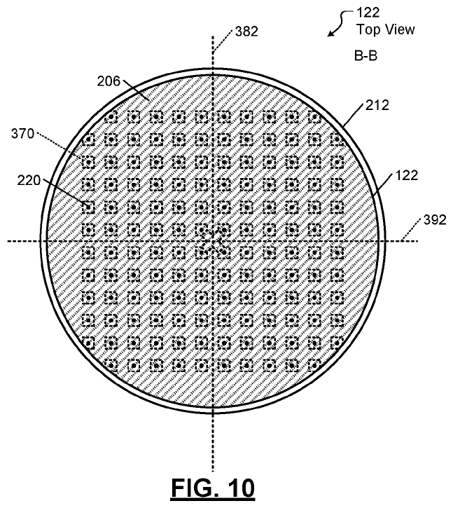

A heater used in the upper plenum of the dual plenum showerhead is shown and described in further detail with reference to FIGS. 6A and 6B. An example of an adapter for the dual plenum showerhead according to the present disclosure is shown and described in further detail with reference to FIGS. 7A-7C. Examples of the lower plenum formed in the base portion of the dual plenum showerhead are shown and described in further detail with reference to FIGS. 8A and 9C. Through holes formed on the upper surface of the base portion of the dual plenum showerhead are shown and described with reference to FIG. 10. Different patterns of through holes formed on the lower, substrate-facing surface of the base portion are shown and described with reference to FIGS. 11 and 12.

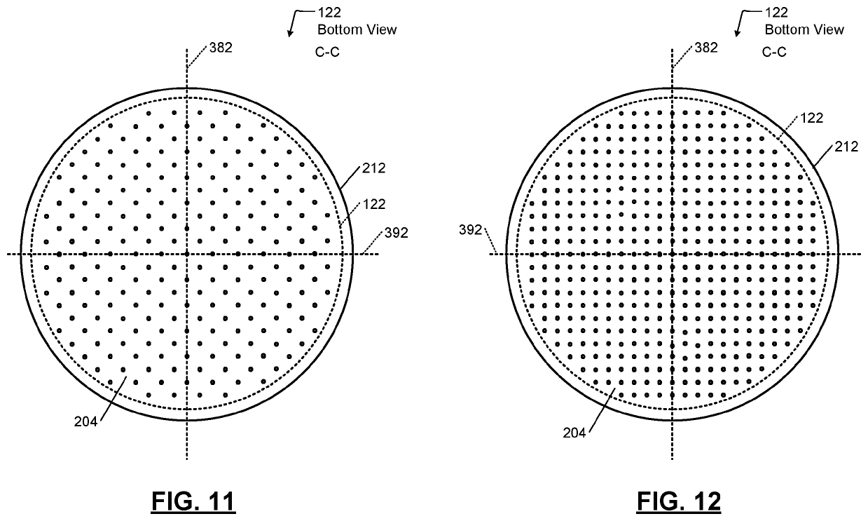

In addition, FIGS. 13-16 show a second example of a dual plenum showerhead comprising through holes of the upper and lower plenums that are optimized to prevent jetting and back diffusion. FIG. 13 shows the second showerhead.

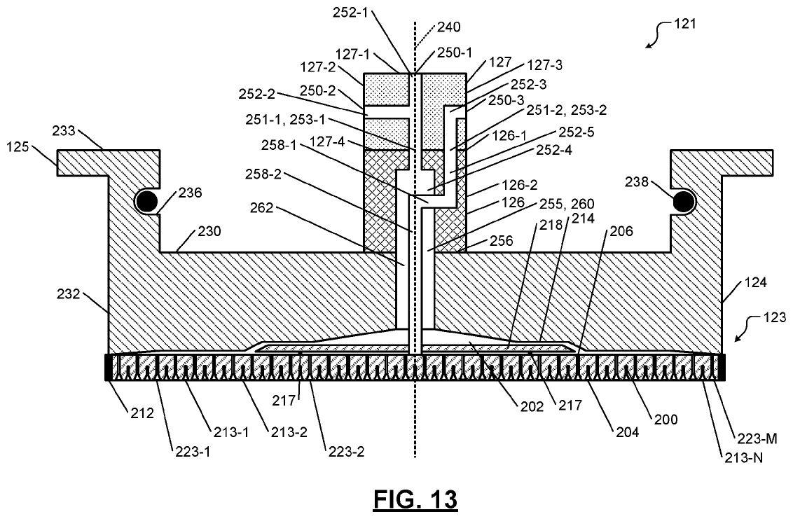

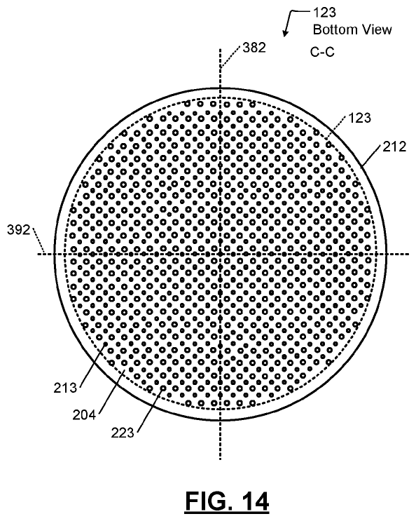

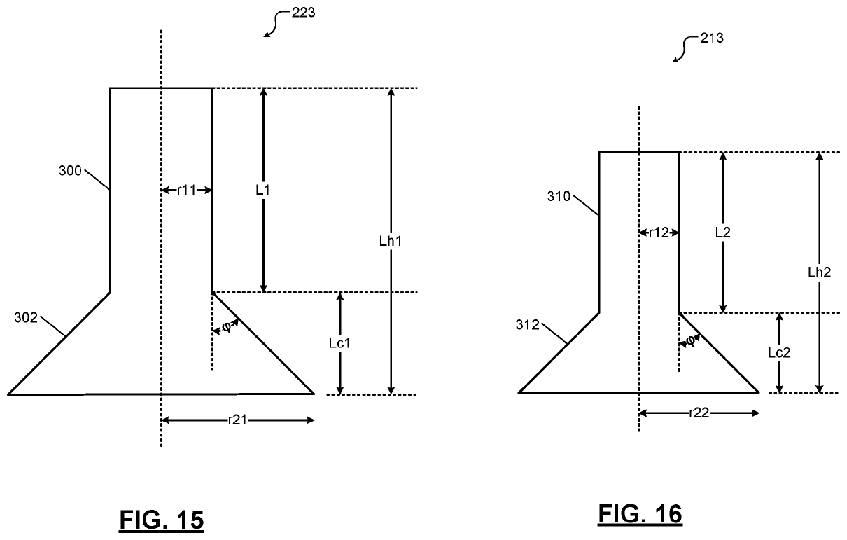

FIG. 14 shows a bottom view of the second showerhead showing different through holes of the upper and lower plenums. FIGS. 15 and 16 show the geometries of the through holes of the upper and lower plenums in further detail.

### Examples of a Tool and a Station

FIG. 1 schematically shows an example of a substrate processing tool 10. For example, the substrate processing tool 10 comprises four (or any number of) stations: a first station 12, a second station 14, a third station 16, and a fourth station 18. For example, each of the stations 12, 14, 16, and 18 may be configured to perform one or more respective processes on a substrate. A transfer robot 20 transfers the substrate between the stations 12, 14, 16, and 18 depending on the processes performed on the substrate in each station.

For example, in some processes, the transfer robot 20 transfers the substrate from the first station 12 to the second station 14, from the second station 14 to the third station 16, and from the third station 16 to the fourth station 18 for processing. After the substrate is processed in the fourth station 18, the transfer robot 20 transfers the substrate to the first station 12. Then the substrate is removed from the first station 12, a new substrate is loaded into the first station 12, and the above cycle is repeated.

FIG. 2 shows an example of a substrate processing system 100 comprising a station 102 configured to process a substrate using a process such as thermal atomic layer deposition (T-ALD), chemical vapor deposition (CVD), plasma enhanced ALD (PEALD), or PECVD. For example, the station 102 comprises any of the stations 12, 14, 16, and 18 of the substrate processing tool 10 shown in FIG. 1.

The station 102 comprises a substrate support (e.g., a pedestal) 104. The pedestal 104 comprises a base portion 106 and a stem portion 108. During processing, a substrate 110 and a ring assembly 111 are arranged on the base portion 106 of the pedestal 104. The substrate 110 is clamped to the base portion 106 of the pedestal 104 using vacuum clamping (not shown). The ring assembly 111 is used to transport the substrate 110 using the transfer robot 20 as described above with reference to FIG. 1. The stem portion 108 is generally Y-shaped. A heater 112 is disposed in the base portion 106 to heat the substrate 110 during processing. One or more temperature sensors 114 are disposed in the base portion 106 to sense the temperature of the pedestal 104.

The station 102 comprises a gas distribution device 120 such as a dual plenum showerhead. The dual plenum showerhead (hereinafter the showerhead) 120 is shown and described below in detail with reference to FIGS. 3-12. Briefly, the showerhead 120 is used to introduce and distribute process gases into the station 102. The showerhead 120 is made of a metal such as aluminum or an alloy. The showerhead 120 comprises a base portion 122, a backplate 124, and a stem portion 126. An adapter 127 comprising a cooling channel (see FIGS. 7A-7D) is attached to the stem portion 126. The base portion 122, the backplate 124, the stem portion 126, and the adapter 127 are shown and described below in further detail with reference to FIGS. 3-12.

Briefly, the base portion 122 is attached to the backplate 124. The base portion 122 and the backplate 124 are generally cylindrical. The base portion 122 comprises a first (lower) plenum (see FIGS. 3 and 8A-9C). The backplate 124 comprises a second (upper) plenum (see FIGS. 3-4B). An upper end of the backplate 124 comprises a flange 125 that extends radially outwardly and that is attached to a sidewall of the station 102. One end of the stem portion 126 is attached to the center of the backplate 124. A distal end of the stem portion 126 is attached to the adapter 127. The stem portion 126 and the adapter 127 comprise bores (see FIG. 3) through which process gases are supplied to the upper and lower plenums of the showerhead 120.

A substrate-facing surface of the base portion 122 comprises a plurality of outlets or features (e.g., slots or through holes; see FIGS. 11 and 12) through which the process gases flow into the station 102. The showerhead 120 comprise a heater, which is shown and described below in further detail with reference to FIGS. 3, 6A, and 6B. The showerhead 120 comprises one or more temperature sensors 128 to sense the temperature of the showerhead 120.

A gas delivery system 130 comprises a plurality of gas sources 132-1, 132-2, . . . , and 132-N (collectively, the gas sources 132), where N is a positive integer. The gas sources 132 are connected by valves 134-1, 134-2, . . . , and 134-N(collectively, the valves 134) to mass flow controllers 136-1, 136-2, . . . , and 136-N(collectively, the mass flow controllers 136). The gas sources 132 may supply process gases, purge gases, inert gases, cleaning gases, and so on to the station 102. One or more of the gas sources 132 supply process gases to the upper plenum of the showerhead 120 via a manifold 140. One or more of the gas sources 132 supply process gases to the lower plenum of the showerhead 120. Further, while not shown, when plasma is used, the substrate processing system 100 may also comprise an RF power supply to supply RF power to the showerhead 120 to strike plasma.

A cooling assembly 150 is mounted at the base of the stem portion 108 of the pedestal 104. A coolant supply 152 supplies a coolant (e.g., water) to the cooling assembly 150 through a valve 154. The coolant flowing through the cooling assembly 150 draws heat from the stem portion 108 of the pedestal 104. A pedestal lift assembly 155 is attached to cooling assembly 150. The pedestal lift assembly 155 moves the pedestal 104 vertically up and down relative to the showerhead 120.

The coolant supply 152 also supplies the coolant to the cooling channel in the adapter 127 through a valve 157. The coolant flowing through the cooling channel in the adapter 127 draws heat from the stem portion 126 of the showerhead 120. The adapter 127 cooled by the coolant reduces the amount of heat transferred from the stem portion 126 of the showerhead 120 to the manifold 140. Further, the coolant supply 152 supplies the coolant to the heater in the showerhead 120 (see FIGS. 3, 6A, and 6B) to control the temperature of the showerhead 120.

A controller 160 controls the components of the substrate processing system 100. The controller 160 is connected to the heater 112 in the pedestal 104, the heater in the showerhead 120, and the temperature sensors 114 and 128 in the pedestal 104 and the showerhead 120. The controller 160 controls the power supplied to the heater 112 to control the temperature of the pedestal 104. The controller 160 also controls power supplied to the heater disposed in the showerhead 120 to control the temperature of the showerhead 120. The controller 160 controls the power supplied to the heaters in the pedestal 104 and the showerhead 120 based on feedback received from the temperature sensors 114 and 128 disposed in the pedestal 104 and the showerhead 120, respectively.

The controller 160 controls the supply of the coolant to the adapter 127 by controlling the valve 157 based on the temperature of the showerhead 120 sensed by the temperature sensor 128. The controller 160 also controls the supply of the coolant to the cooling assembly 150 by controlling the coolant supply 152 and the valve 154 based on the temperature of the pedestal 104 sensed by the temperature sensor 114. The controller 160 controls the pedestal lift assembly 155 to control a gap between the pedestal 104 (and the substrate 110) and the showerhead 120.

A vacuum pump 158 maintains sub-atmospheric pressure inside the station 102 during substrate processing. A valve 156 is connected to an exhaust port of the station 102. The valve 156 and the vacuum pump 158 are used to control pressure in the station 102 and to evacuate reactants from the station 102 via the valve 156. The controller 160 controls the vacuum pump 158 and the valve 156.

### Dual Plenum Showerhead

FIG. 3 shows the dual plenum showerhead (hereinafter the showerhead) 120 in further detail. All of the components of the showerhead 120 described below are made of a metallic material (e.g., aluminum or an alloy). The showerhead 120 comprises the base portion 122, the backplate 124, and the stem portion 126. The base portion 122 is attached to the backplate 124. The base portion 122 and the backplate 124 are generally cylindrical. The base portion 122 comprises a first (lower) plenum 200, which is shown and described below in further detail with reference to FIGS. 8A-9C. The backplate 124 comprises a second (upper) plenum 202, which is shown and described below in further detail with reference to FIGS. 4A and 4B.

Briefly, the lower plenum 200 is formed by diametrically cross-drilling bores (see FIGS. 8A-9C) through the base portion 122. The cross-drilling forms vertical pillars (see FIGS. 8A-9C) between a lower, substrate-facing surface 204 and an upper surface 206 of the base portion 122. A set of first through holes 210-1, 210-2, . . . , and 210-N (collectively the first through holes 210), where N is a positive integer, are drilled from the lower surface 204 of the base portion 122 into the first plenum 200. The first through holes 210 extend vertically from the lower surface 204 of the base portion 122 into the lower plenum 200 as shown and described below in further detail with reference to FIGS. 8A-9C. The first through holes 210 have a first diameter. The first through holes 210 are in fluid communication with the lower plenum 200. A ring 212 is attached to the periphery (e.g., sidewall) of the base portion 122 to enclose the bores cross-drilled in the base portion 122. Alternatively, plugs (not shown) may be inserted into the bores cross-drilled in the base portion 122. For example, the ring 212 may comprise a clamp. Thus, the lower and upper surfaces 204, 206 of the base portion 122 and the ring 212 define the lower plenum 200.

The upper plenum 202 is defined in the backplate 124 by removing material from a bottom region 214 of the backplate 124. The material is removed such that the bottom region 214 of the backplate 124 has a predefined profile (shape), which is shown and described below in further detail with reference to FIGS. 4A and 4B. Briefly, the bottom region 214 of the backplate 124 tapers (slopes) at various angles from the center to the edge of the bottom region 214 of the backplate 124. When the base portion 122 is attached to the backplate 124, the upper surface 206 of the base portion 122 and the bottom region 214 of the backplate 124 define the upper plenum 202.

A set of second through holes 220-1, 220-2, . . . , and 210-M (collectively the second through holes 220), where M is a positive integer, are drilled in the pillars formed in the base portion 122. The second through holes 220 extend vertically from the lower surface 204 to the upper surface 206 of the base portion 122 into the upper plenum 202. The second through holes 220 have a second diameter. The second diameter may or may not be the same as the first diameter of the first through holes 210. The second through holes 220 are in fluid communication with the upper plenum 202. The second through holes 220 and the upper plenum 202 are disjoint (separate) from the first through holes 210 and the lower plenum 200. Accordingly, second through holes 220 and the upper plenum 202 are not in fluid communication with the first through holes 210 and the lower plenum 200.

A baffle plate 218 is disposed in the upper plenum 202. The baffle plate 218 is attached to the upper surface 206 of the base portion 122 using suitable fasteners shown at 217. The baffle plate 218 is shown and described below in further detail with reference to FIG. 5. Briefly, the baffle plate 218 is flat, generally cylindrical, and tapers at the edges to conform with the profile of the upper plenum 202. The baffle plate 218 has a smaller diameter than the backplate 124 and the base portion 122 of the showerhead 120. The baffle plate 218 comprises through holes (see FIG. 5) arranged in concentric circles. The diameters of the through holes in the baffle plate 218 increase from the center to the end of the baffle plate 218.

The through holes in the baffle plate 218 may or may not align with the second through holes 220. However, the through holes in the baffle plate 218 are in fluid communication with the second through holes 220 and the upper plenum 202. The through holes in the baffle plate 218 are not in fluid communication with the first through holes 210 and the lower plenum 202. The baffle plate 218 uniformly distributes the process gases flowing through the upper plenum 202 via the second through holes 220. Specifically, due to their varying diameters, the through holes in the baffle plate 218 distribute the process gases uniformly from the center to the edge of the baffle plate 218 through the second through holes 220.

The backplate 124 comprises an upper surface 230 and a sidewall 232. The sidewall 232 extends vertically upwards from an outer diameter (OD) of the bottom region 214 of the backplate 124. That is, the sidewall 232 extends perpendicularly along an axis 240 of the showerhead 120 in a direction opposite to the base portion 122. The upper surface 230 of the backplate 124 is perpendicular to the axis 240 of the showerhead and is parallel to the base portion 122. The upper surface 230 extends radially to an inner diameter (ID) of the sidewall 232.

A portion of the sidewall 232 extends vertically above the upper surface 230 parallel to the axis 240 of the showerhead 120. A height of the sidewall 232 is a distance between the OD of the bottom region 214 of the backplate 124 and a distal end 233 of the sidewall 232. A distance from the OD of the bottom region 214 of the backplate 124 to the upper surface 230 of the backplate 124 is less than the height of the sidewall 232.

The distal end 233 of the sidewall 232 comprises the flange 125 that extends radially outwardly from the OD of the sidewall 232. The flange 125 is attached to the sidewall of the station 102 as shown and described above with reference to FIG. 2. The distal end 233 of sidewall 232 comprises a groove 236 along the ID of the sidewall 232. The groove 236 is located opposite to the flange 125. A heater 238 is disposed in the groove 236. The heater 238 heats the backplate 124. The heater 238 is shown and described below in further detail with reference to FIGS. 6A and 6B.

The stem portion 126 of the showerhead 120 is attached to the center of the upper surface 230 of the backplate 124. The stem portion 126 is generally cylindrical. The stem portion 126 extends vertically from the center of the upper surface 230 along the axis 240 of the showerhead 120. The stem portion 126 has a smaller diameter than the backplate 124 and the base portion 122. A height of the stem portion 126 is less than or equal to a distance between the upper surface 230 of the backplate 124 and the distal end 233 of the sidewall 232. The adapter 127 is attached to a distal end 126-1 of the stem portion 126. The adapter 127, along with the cooling channel, is shown and described below in further detail with reference to FIGS. 7A-7C.

The stem portion 126 and the adapter 127 comprise inlets, outlets, bores, and conduits (collectively called passages) through which process gases are supplied to the upper and lower plenums 202, 200 of the showerhead 120 as follows. In the examples of the passages described below, an example of an arrangement of various inlets, outlets, bores, and conduits is described. Alternate arrangements of inlets, outlets, bores, and conduits can be used instead.

For example, the adapter 127 comprises a first inlet 250-1, a second inlet 250-2, and a third inlet 250-3 (collectively the inlets 250). The adapter 127 comprises a first outlet 251-1 and a second outlet 251-2 (collectively the outlets 251). The first inlet 250-1 is located on a top surface 127-1 of the adapter 127. The second inlet 250-2 is located on a first side surface 127-2 of the adapter 127. The third inlet 250-3 is located on a second side surface 127-3 of the adapter 127. The outlets 251 are located on a bottom surface 127-4 of the adapter 127. For example, the first inlet 250-1 is connected to the manifold 140 (shown in FIG. 2). The second inlet 250-2 may be connected to another manifold (not shown), which in turn may receive one or more gases from the gas sources 130 (shown in FIG. 2). The third inlet 250-3 may be connected to yet another manifold (not shown), which in turn may receive one or more gases from the gas sources 132 (shown in FIG. 2).

A first bore 252-1 is drilled through the adapter 127 along the axis 240 of the showerhead 120. The first bore 252-1 extends from the first inlet 250-1 through the adapter 127 to the first outlet 251-1 of the adapter 127. The first inlet 250-1, the first bore 252-1, and the first outlet 251-1 of the adapter 127 are aligned with the axis 240 of the showerhead 120. A second bore 252-2 is drilled through the adapter 127 perpendicularly to the axis 240 of the showerhead 120. The second bore 252-2 extends from the second inlet 250-2 through the adapter 127 and connects to the first bore 252-1. A third bore 252-3 is drilled through the adapter 127 perpendicularly to the axis 240 of the showerhead 120. The third bore 252-3 extends from the third inlet 250-3 through the adapter 127, turns downwardly towards the bottom surface 127-4 of the adapter 127, and extends to the second outlet 251-2 parallel to the axis 240 of the showerhead 120.

The stem portion 126 comprises a first inlet 253-1 and a second inlet 253-2 (collectively the inlets 253). The inlets 253 are located on the distal end 126-1 of the stem portion 126. When the adapter 127 is attached to the stem portion 126, the bottom surface 127-4 of the adapter is attached to the distal end 126-1 of the stem portion 126. The first outlet 251-1 and the second outlet 251-2 of the adapter 127 mate with the first inlet 253-1 and the second inlet 253-2 of the stem portion 126, respectively. The stem portion 126 comprises an outlet 255. The outlet 255 is located on a bottom surface 256 of the stem portion 126 that is attached to the upper surface 230 of the backplate 124.

A fourth bore 252-4 is drilled through the stem portion 126 along the axis 240 of the showerhead 120. The fourth bore 252-4 extends from the first inlet 253-1 through the stem portion 126 to the outlet 255 of the stem portion 126. The first inlet 253-1, the fourth bore 252-4, and the outlet 255 of the stem portion 126 are aligned with the axis 240 of the showerhead 120. A first portion of the fourth bore 252-4 connected to the first inlet 253-1 of the stem portion 126, the first inlet 253-1, and the first outlet 251-1 of the adapter 127 have the same diameter (called a first diameter). A second portion of the fourth bore 252-4 that extends from the first portion of the fourth bore 252-4 to the outlet 255 of the stem portion 126, and the outlet 255 have the same diameter (called a second diameter). The second diameter is greater than the first diameter.

A fifth bore 252-5 is drilled through the stem portion 126 along the axis 240 of the showerhead 120. The fifth bore 252-5 is parallel to the fourth bore 252-4. A first conduit 258-1 is inserted through a corresponding bore (not shown) drilled in the stem portion 126 from a side 126-2 of the stem portion 126. A distal end of the conduit 258-1 and the corresponding bore extend perpendicularly to the axis 240 of the showerhead 120 towards the center of the stem portion 126 and into the fourth bore 252-4. After inserting the first conduit 258-1, the corresponding bore is closed at the side 126-2 of the stem portion 126 (e.g., using a plug). A second conduit 258-2 is inserted through the outlet 255 of the stem portion 126. A distal end of the second conduit 258-2 is attached to the distal end of the first conduit 258-1 at the center of the stem portion 126.

The backplate 124 comprises an inlet 260 at the upper surface 230 of the backplate 124. When the stem portion 126 is attached to the backplate 124, the outlet 255 of the stem portion 126 mates with the inlet 260 of the backplate 124. The outlet 255 of the stem portion 126 has the same diameter as the inlet 260 of the backplate 124. A bore 262 is drilled through the backplate 124 along the axis 240 of the showerhead 120. The bore 262 extends from the inlet 260 and extends into the upper plenum 202. The bore 262 has the same diameter as the second portion of the fourth bore 252-4. The second conduit 258-2 extends through the bore 262, the upper plenum 202, and the center of the baffle plate 218. The second conduit 258-2 is connected to the lower plenum 200. The second conduit 258-2 is not in fluid communication with the bore 262.

The first inlet 250-1, the second inlet 250-2, the first bore 252-1, the second bore 252-2, the first outlet 251-1, the first inlet 253-1, the fourth bore 252-4, the outlet 255, the inlet 260, the bore 262, the upper plenum 202, the through holes of the baffle plate 218, and the second through holes 220 (called the first set of elements) are in fluid communication with each other.

The third inlet 250-3, the third bore 252-3, the second outlet 251-2, the second inlet 253-2, the fifth bore 252-5, the first and second conduits 258-1, 258-2, the lower plenum 200, and the first through holes 210 (called the second set of elements) are in fluid communication with each other. The first and second sets of elements are not in fluid communication with each other. Accordingly, gases flowing through the first set of elements do not mix with gases flowing through the second set of elements in the showerhead 120.

Again, while an example of an arrangement of the various inlets, outlets, bores, and conduits (collectively the passages) is described above, the inlets, outlets, bores, and conduits can be arranged in alternate ways such that the upper and lower plenums 202, 202 remain disjoint and the gases supplied through the upper and lower plenums 202, 202 do not mix in the showerhead 120.

### Elements of Dual Plenum Showerhead

The profile of the upper plenum 202 is shown and described in further detail with reference to FIGS. 4A and 4B. The baffle plate 218 is shown and described in further detail with reference to FIG. 5. The heater 238 is shown and described in further detail with reference to FIGS. 6A and 6B. The adapter 127 and the stem portion 126 are shown and described in further detail with reference to FIGS. 7A-7F. Cross-sectional views of the lower plenum 200 taken along lines A-A shown in FIG. 3 are shown and described in further detail with reference to FIGS. 8A-9C. A plan view of the base portion 122 (i.e., a cross-sectional view of the showerhead 120 taken along lines B-B shown in FIG. 3) is shown and described in further detail with reference to FIG. 10. Bottom views of the showerhead 120 (i.e., cross-sectional views of the showerhead 120 taken along lines B-B shown in FIG. 3) are shown and described in further detail with reference to FIGS. 11 and 12.

### Upper Plenum

FIGS. 4A and 4B show the profile (shape) of the upper plenum 202 of the showerhead 120 in further detail. Other details of the showerhead 120 shown in FIG. 3 are omitted but are presumed present in FIGS. 4A and 4B. FIG. 4A shows the profile of the upper plenum 202 with the baffle plate 218 present. FIG. 4B shows the profile of the upper plenum 202 without the baffle plate 218 (i.e., with the baffle plate 218 taken out of the showerhead 120).

In FIG. 4A, the upper plenum 202 tapers radially from the center of the backplate 124 to the OD of the bottom region 214 of the backplate 124 at various angles. The tapering (shaping) of the bottom region 214 of the backplate 124 is described only on a first half portion of the backplate 124. The tapering (shaping) of the bottom region 214 on a second half portion of the backplate 124 is a mirror image of the tapering (shaping) of the bottom region 214 on the first half portion of the backplate 124. The following description is only an example of the tapering (shaping) of the bottom region 214. The distances and angles can be varied. The number of portions can also be varied. In the following description, a direction perpendicular to the axis 240 of the showerhead 120 is the same as parallel to the upper surface 230 of the backplate 124, and parallel to the lower and upper surfaces 204, 206 of the base portion 122. The angles are relative to a plane perpendicular to the axis 240 of the showerhead 120.

For example, a first portion 270 of the bottom region 214 extends radially towards the OD of the backplate 124 from the center of the backplate 124 perpendicularly to the axis 240 of the showerhead 120 for a first distance d1. Then a second portion 272 of the bottom region 214 extends from the first portion 270 towards the OD of the backplate 124 and slopes downwardly towards the base portion 122 (i.e., away from the upper surface 230 of the backplate 124) at a first angle for a second distance d2. Then a third portion 274 of the bottom region 214 extends from the second portion 272 and extends radially towards the OD of the backplate 124 perpendicularly to the axis 240 of the showerhead 120 for a third distance d3.

Then a fourth portion 276 of the bottom region 214 extends from the third portion 274 towards the OD of the backplate 124 and slopes downwardly towards the base portion 122 (i.e., away from the upper surface 230 of the backplate 124) at a second angle for a fourth distance d4. Then a fifth portion 278 of the bottom region 214 extends from the fourth portion 276 and extends radially towards the OD of the backplate 124 perpendicularly to the axis 240 of the showerhead 120 for a fifth distance d5. Then a sixth portion 280 of the bottom region 214 extends from the fifth portion 278 towards the OD of the backplate 124 and slopes downwardly towards the base portion 122 (i.e., away from the upper surface 230 of the backplate 124) up to the OD of the backplate 124 at a third angle for a sixth distance d6.

For example, d1<d2, d1<d3, d1<d5, d1<d6, d1 is approximately equal to d4; d2>d3, d2>d4, d2<d5, and d2>d6; d3>d1, d3<d2, d3>d4, d3<d5, and d3<d6; d4 is approximately equal to d1, and d4 is less than each of d2, d3, d5, and d6; d5 is greater than each of d1, d2, d3, d4, and d6; and d6 is greater than each of d1 and d4, and d6 is less than each of d2, d3, and d5. For example, a sum of the distances d1, d2, and d3 is approximately equal to a diameter of the baffle plate 218. The diameter of the baffle plate is approximately half of the OD of the sidewall 232 (i.e., the OD of the backplate 124). For example, the sum of the distances d1, d2, and d3 is approximately equal to a sum of the distances. In other examples, any of the distances d1 through d6 can be varied in any other way. Further the number of portions can be added or reduced.

For example, the first angle is less than the second angle and greater than the third angle. The second angle is greater than the first and third angles. The third angle is less than the first and second angles. In other examples, any of these angles can be varied in any other way. Further, the number of angles can be added or reduced.

In general, the backplate 124 comprises a shaped surface (the bottom region 214) extending from a center portion of the backplate 124 to a periphery (OD) of the backplate 124. The shaped surface (the bottom region 214) comprises a plurality of portions or segments (e.g., elements 270 to 280). At least one of the portions of the shaped surface (the bottom region 214) is parallel to the base portion 122 (e.g., elements 270, 274, 278). At least one of the portions of the shaped surface (the bottom region 214) slopes towards the base portion 122 (e.g., elements 272, 276, 280). The periphery of the backplate 124 is attached to the upper surface 206 of the base portion 122. The shaped surface (the bottom region 214) of the backplate 124 and the upper surface 206 of the base portion 122 define the upper plenum 202.

FIG. 4B shows the profile of the upper plenum 202 without the baffle plate 218. The profile reduces the volume of the upper plenum 202 compared to a typical cylindrical plenum 201. FIG. 4B also shows a side view of the baffle plate 218. A thickness t (i.e., height) of the baffle plate 218 is less than half of a distance d7 between the upper surface 206 of the base portion 122 and the center of the bottom region 214 of the backplate 124.

Further, the thickness t of the baffle plate 218 is less than a distance between the upper surface 206 of the base portion 122 and at least one of the portions of the shaped surface (the bottom region 214) that is parallel to the base portion 122 and that lies within the radius of the baffle plate 218 (e.g., elements 270, 274). The thickness t of the baffle plate 218 is also less than a distance between the upper surface 206 of the base portion 122 and at least one of the portions of the shaped surface (the bottom region 214) that slopes towards the base portion 122 and that lies within the radius of the baffle plate 218 (e.g., elements 272, 276).

Furthermore, the thickness t of the baffle plate 218 is greater than a distance between the upper surface 206 of the base portion 122 and at least one of the portions of the shaped surface (the bottom region 214) that is parallel to the base portion 122 and that lies outside the radius of the plate (e.g., element 278). The thickness t of the baffle plate 218 is less than a distance between the upper surface 206 of the base portion 122 and at least one of the portions of the shaped surface (the bottom region 214) that slopes towards the base portion 122 and that lies outside the radius of the baffle plate 218 (e.g., element 280).

The baffle plate 218 comprises an opening 219 at the center through which the second conduit 258-2 (shown in FIG. 3) passes and connects to the lower plenum 200. The baffle plate 218 is tapered near the periphery (i.e., at the edge or OD) 221. While not shown, the edge 221 of the baffle plate may be rounded instead of tapering at an angle as shown.

### Baffle Plate

FIG. 5 shows a plan view of the baffle plate 218. The baffle plate comprises multiple sets of through holes 290-1, 290-2, 290-3, and so on (collectively the though holes 290) arranged in respective concentric circles. While only four through holes 290 are shown on each circle for simplicity of illustration, numerous through holes 290 can be arranged on each circle. The circles and the through holes 290 can extend in all the directions shown by arrows up to the OD of the baffle plate 218.

The through holes 290-1 on a first circle of a first radius R1 have a first diameter D1. The through holes 290-2 on a second circle of a second radius R2 have a second diameter D2. The through holes 290-3 on a third circle of a third radius R3 have a third diameter D3, and so on, where R1>R2>R3 and so on, and where D1<D2<D3 and so on. That is, the diameter of the through holes 290 increases proportionally with the radial distance of the through holes 290 from the center of the baffle plate 218. On each circle, the through holes 290 are spaced equidistantly from each other. The through holes 290 can be arranged on the circles in many different ways.

In some examples, the through holes 290 may be arranged in different patterns. For example, on some of the circles, some of the through holes 290 may be omitted. For example, the spacing between the through holes 290 within the circles may vary from one circle to another. For example, the through holes 290 may be grouped differently in different circles. For example, there may be offsets between the through holes 290 on alternate circles. Many other variations in the arrangements of the through holes 290 are possible.

Further, the through holes 290 may be arranged on shapes other than circles. For example, the through holes 290 may be arranged on concentric polygons. For example, the through holes 290 may be arranged in zones (e.g., in shapes of a pie). For example, the through holes 290 may be arranged using a combination of shapes. Furthermore, the shape of the through holes 290 can be varied. For example, the through holes 290 can be polygonal. For example, the through holes 290 may be hexagonal, triangular, and so on. Any combination of these shapes may be used. In addition, any of the above variations in the layouts, shapes and sizes of the through holes 290 may be combined.

### Showerhead Heater

FIGS. 6A and 6B show the heater 238 in further detail. The heater 238 comprises a conduit (see FIG. 6B) through which the coolant supplied by the coolant supply 152 shown in FIG. 2 is circulated. The arrows show the direction in which the coolant flows through the conduit. The heater 238 controls the temperature of the backplate 124. The controller 160 shown in FIG. 2 controls the temperature of the coolant through the heater 238 based on feedback from the temperature sensor 128 (see FIG. 2) disposed in the backplate 124. The controller 160 controls the flow rate of the coolant through the heater 238 by controlling the valve 157 shown in FIG. 2. The heater 238 is used to heat the backplate 124 to control the temperature of the gases flowing through the showerhead 120. The heater 238 also regulates the temperature of the showerhead 120 since the showerhead 120 receives heat from the pedestal 104 (see FIG. 2). Additionally, the adapter 127 prevents heat transfer from the showerhead 120 to the manifold 140 (see FIG. 2) as follows.

### Showerhead Adapter

FIGS. 7A-7F show the adapter 127 and the stem portion 126 in further detail. FIGS. 7A-7D show various view of the adapter showing the cooling channel in the adapter 127. The arrows show the direction in which the coolant flows through the cooling channel. FIGS. 7A-7D also show the inlets and outlets of the adapter 127 which are described above in detail with reference to FIG. 3. Note that the adapter 127 and the cooling channel can have different shapes than those shown. FIGS. 7E and 7F show views of the stem portion 126 showing the inlets that mate with the outlets of the adapter 127 and showing the outlet that mates with the backplate 124, which are described above in detail with reference to FIG. 3.

FIG. 7A shows a top view of the adapter 127 showing the first inlet 250-1 and the cooling channel. FIG. 7B shows a side view of the adapter 127 showing the cooling channel in further detail. FIG. 7C shows a front view of the adapter 127 showing the cooling channel in still further detail. FIG. 7D shows a bottom view of the adapter 127 showing the first and second outlets 251-1, 251-2 and the cooling channel.

In FIGS. 7B and 7C, the adapter 127 comprises a groove 129 in which a conduit 131 is disposed. The groove 129 is disposed in the adapter 127 on the second side surface 127-3 of the adapter 127. The groove 129 extends from near the bottom surface 127-4 of the adapter 127, which is proximate to the distal end 126-1 (i.e., top end) of the stem portion 126, to near the top surface 127-1 of the adapter 127. The groove 129 begins on the second side surface 127-3 of the adapter 127 from near the bottom surface 127-4 of the adapter 127. The groove 129 extends into the adapter 127 towards the center of the adapter 127 up to a distance that is less than half the width (or radius, if the adapter 127 is cylindrical) of the adapter 127. The width of the adapter 127 is a distance between the second side surface 127-3 and the first side surface 127-2 of the adapter 127. Then the groove 129 extends upwards through the adapter 127 towards the top surface 127-1 of the adapter 127. Then the groove 129 extends outwardly towards the second side surface 127-3 near the top surface 127-1 of the adapter 127. The groove 129 ends on the second side surface 127-3 of the adapter 127 near the top surface 127-1 of the adapter 127. Thus, the groove 129 is generally U-shaped. However, the groove 129 can be of any other shape (e.g., V-shape, S-shape, of the shape of the symbol Ω, etc.). A conduit 131 having the shape of the groove 129 is disposed in the groove 129. The coolant supplied by the coolant supply 152 (shown in FIG. 2) is circulated through the conduit 131 to cool the adapter 127.

FIGS. 7E and 7F show top and bottom views of the stem portion 126, respectively. FIG. 7E shows a top surface of the stem portion 126 at the distal end 126-1 of the stem portion 126 with the first and second inlets 253-1, 253-2 of the stem portion 126. The top surface of the stem portion 126 is attached to the bottom surface 127-4 of the adapter 127. The first and second inlets 253-1, 253-2 of the stem portion 126 mate with the first and second outlets 251-1, 251-2 of the adapter 127 as described above in detail with reference to FIG. 3. FIG. 7F shows the bottom surface 256 of the stem portion 126 with the outlet 255 and the second conduit 258-2, which are described above in detail with reference to FIG. 3.

### Lower Plenum

FIGS. 8A-9C show the lower plenum 200 in further detail. FIGS. 8A-9C show two examples of the lower plenum 200. In a first example, FIGS. 8A-8C show a first configuration of the lower plenum 200. In a second example, FIGS. 9A-9C show a second alternate configuration of the lower plenum 200 with more through holes 210 than in the first configuration as described below in detail.

Specifically, FIGS. 8A-9C show two examples of cross-sections of the base portion 122 taken along lines A-A shown in FIG. 3. FIGS. 8A-8C show a first pattern in which pillars 370 formed by cross-drilling bores in the base portion 122 (described below) and the through holes 210, 220 in the base portion 122 are arranged. FIGS. 9A-9C show a second pattern in which the pillars 370 and the through holes 210, 220 are arranged. The second pattern differs from the first pattern in that the second pattern comprises additional through holes 210 than in the first pattern as explained below in detail. Some of the through holes 210 not visible in FIGS. 8A and 9A are shown in detail in FIGS. 8B, 8C, 9B, and 9C.

In FIGS. 8A and 9A, the base portion 122 comprises the lower plenum 200 defined by a plurality of bores drilled horizontally through the base portion 122. The lower plenum 200 and the bores are shown and as described below in detail. Briefly, at least two sets of bores are cross-drilled through the base portion 122 forming vertical pillars 370 at the intersections of the cross-drilled bores. The through holes 210 are drilled around the pillars 370 from the lower surface 204 of the base portion 122. The through holes 210 extend from the lower surface 204 of the base portion 122 into the lower plenum 200 defined by the cross-drilled bores. The through holes 220 are drilled through the pillars 370 from the lower surface 204 of the base portion 122. The through holes 220 extend through the base portion 122 via the pillars 370 into the upper plenum 202 defined by the backplate 124 as described above. The lower plenum 200 and through holes 210, 220 are now described below in further detail.

FIGS. 8A and 9A show a cross-section of the showerhead 120 taken along lines A-A shown in FIG. 3. The cross-section A-A shows the cross-drilled bores and the lower plenum 200. Two sets of bores are cross-drilled laterally through the sidewall of the base portion 122 orthogonally (i.e., perpendicular to each other). Specifically, a first set of bores 380-1, 380-2, 380-3, . . . , 380-N(collectively, the first set of bores 380), where N is a positive integer, is drilled horizontally (i.e., perpendicular to the axis 240 of the showerhead 120) through the base portion 122. The first set of bores 380 is drilled along a first axis 382 (i.e., along chords of the base portion 122 parallel to the first axis 382). A second set of bores 390-1, 390-2, 390-3, . . . , 390-N(collectively, the second set of bores 390), where N is a positive integer, is drilled horizontally (i.e., perpendicular to the axis 240 of the showerhead 120) through the base portion 122. The second set of bores 390 is drilled along a second axis 392 (i.e., along chords of the base portion 122 parallel to the second axis 392). The first axis 382 is perpendicular to the second axis 392. The first and second sets of bores 380, 390 and the sidewall of the base portion 122 around which the ring 212 is attached define the lower plenum 200 within the base portion 122.

The first and second sets of bores 380, 390 create pillars 370-1, 370-2, 370-3, . . . , and 370-M (collectively, the pillars 370), where M is a positive integer greater than N, at the intersections of the first and second sets of bores 380, 390. Specifically, since the first and second sets of bores 380, 390 are drilled perpendicularly to each other, the pillars 370 are rectangular in shape. More specifically, in the example shown, the bores in the first and second sets of bores 380, 390 are of equal diameter and are equidistant from each other. Consequently, the pillars 370 are square in shape. The pillars 370 extend vertically from the lower surface 204 to the upper surface 206 of the base portion 122. The pillars 370 are distributed from the center of the base portion 122 to the OD of the base portion 122 as shown and as described below in detail.

The through holes 210 are drilled around the pillars 370 from the lower surface 204 of the base portion 122 into the lower plenum 200 (i.e., into spaces between the pillars 370). The through holes 210 are distributed radially from the center of the base portion 122 to the OD of the base portion 122. Some of the through holes 210 are not visible in FIGS. 8A and 9A and are shown in detail in FIGS. 8B, 8C, 9B, and 9C.

Additionally, since the showerhead 120 comprises the upper plenum 202, the pillars 370 in the first and second patterns shown in FIGS. 8A-9C comprise the through holes 220. The through holes 220 are drilled through the pillars 370 from the lower surface 204 to the upper surface 206 of the base portion 122.

In FIGS. 8A-9C, the first and second sets of bores 380, 390 are drilled such that the center of the base portion 122 has a through hole 210 instead of a pillar 370. The bores in the first and second sets of bores 380, 390 intersect at the center of the base portion 122. However, while not shown, the first and second sets of bores 380, 390 can be drilled such that the center of the base portion 122 has a pillar 370 instead of a through hole 210.

FIGS. 8C and 9C show the arrangements of the pillars 370 and the through holes 210, 220 at the center of the base portion 122. FIGS. 8B and 9B show the arrangements of the pillars 370 and the through holes 210, 220 in the remainder of the base portion 122 (i.e., in the region of the base portion 122 that is radially outward from the center of the base portion 122).

In FIG. 8A, subsequent to the pattern shown in FIG. 8C, in the region of the base portion 122 that is radially outward from the center of the base portion 122, the pattern of the pillars 370, the through holes 220, and the through holes 210 shown in FIG. 8B, extends (i.e., replicates) along the first and second axes 382, 392.

In FIG. 9A, subsequent to the pattern shown in FIG. 9C, in the region of the base portion 122 that is radially outward from the center of the base portion 122, the pattern of the pillars 370, the through holes 220, and the through holes 210 shown in FIG. 9B, extends (i.e., replicates) along the first and second axes 382, 392.

As shown in FIGS. 8B and 9B, when the bores in the first and second sets of bores 380, 390 are of equal diameter and are equidistant from each other, four pillars 370 lie on vertices of a square 371. The four pillars 370 include two pillars 370 along the first axis 382 and two pillars 370 along the second axis 392. One pillar 370 lies at the center of the square 371 (i.e., at the intersection of the diagonals of the square 371, which lie along the first and second axes 382, 392).

In FIGS. 8B and 9B, one through hole 210 lies between each successive pillar 370 at the center of each side of the square 371. The centers of the sides of the square 371 lie on vertices of a square 396. Thus, the four through holes 210 that lie at the centers of the sides of the square 371 lie on the vertices of the square 396, with one pillar 370 at the center of the square 396. The center of the square 396 is the same as the center of the square 371. Accordingly, each pillar 370 is surrounded by four through holes 210. Additionally, four through holes 220 lie on the vertices of the square 371, and one through hole 220 lies at the center of the square 371.

FIG. 9B differs from FIG. 8B in that FIG. 9B shows additional through holes 210 than FIG. 8B. Specifically, in FIG. 9B, one additional through hole 210 lies between each successive pillar 370 along the first and second axes 382, 392. These four additional through holes 210 lie at the centers of the sides of the square 396. Thus, two through holes 210 lie on each diagonal of the square 371. Accordingly, each pillar 370 is surrounded by eight through holes 210. Of the eight through holes 210, a first set of four through holes 210 lie on vertices of a square 396. A second set four through holes 210 lie at the centers of the four sides of the square 396. The second set of four through holes 210 also lie on the diagonals of the square 371.

In the first and second patterns, as shown in FIGS. 8A, 8C, 9A, and 9C, the center of the base portion 122 has a through hole 210. When the bores in the first and second sets of bores 380, 390 are of equal diameter and are equidistant from each other, the centers of the pillars 370 immediately adjacent to the through hole 210 at the center of the base portion 122 lie on vertices of a square 450. Consequently, the through holes 220 in the pillars 370, which are at the center of the respective pillars 370, lie on the vertices of the square 450. The through hole 210 at the center of the base portion 122 lies at the center of the square 450. That is, the through hole 210 at the center of the base portion 122 lies at the intersection of the diagonals of the square 450. The side of the squares 450 and 371 are equal.

In FIG. 9C, in the second pattern, as shown in FIGS. 9A and 9C, the pattern of the pillars 370, the through holes 220, and the through holes 210 is identical to the pattern shown in FIG. 8C except that four additional through holes 210 lie at the centers of the four sides of the square 450.

In some examples, the spacing between the bores in the first set of bores 380 may be different than the spacing in the second set of bores 390. For example, the bores in the first set of bores 380 may be separated from each other by a first distance. The bores in the second set of bores 390 may be separated from each other by a second distance. In other examples, the bores in the first set of bores 380 and/or in the second set of bores 390 may be spaced (i.e., separated from each other) by gradually varying distances. For example, the distance between the bores in the first set of bores 380 and/or in the second set of bores 390 may increase from the center of the base portion 122 towards the circumference of the base portion 122. In some examples, the distance between the bores in the first set of bores 380 and/or in the second set of bores 390 may decrease from the center of the base portion 122 towards the circumference of the base portion 122.

In still other examples, the number of bores in the first set of bores 380 and the second set of bores 390 may be equal. In further examples, some of the bores in the first set of bores 380 and/or in the second set of bores 390 may be omitted. In some examples, the diameters of the bores in the first set of bores 380 and/or in the second set of bores 390 may be varied similar to the spacing variations described above. In still other examples, the bores in the first set of bores 380 and/or in the second set of bores 390 may be arranged in groups. In these still other examples, the spacing (i.e., distance) between the bores and/or the diameters of the bores in the groups may be varied as described above.

Further, the two sets of bores 380, 390 are shown for example only. In some examples additional sets of bores can be drilled creating pillars of different shapes. The variations in quantity (i.e., the number of bores in a set) and/or diameter, the variations in spacing and grouping of the bores described above can be added to these additional sets of bores creating different patterns of pillars. The arrangement of the bores may be dictated by the pattern of the through holes 210 specified by the processes performed on the substrate 110.

FIG. 10 shows a cross-section of the showerhead 120 taken along lines B-B shown in FIG. 3. FIG. 10 shows a top view of the base portion 122 of the showerhead 120 showing the through holes 220 on the upper surface 206 of the base portion 122. The pillars 370 are not visible but are shown in dotted lines to illustrate the alignment of the through holes 220 with the centers of the pillars 370.

For example, FIG. 10 shows the pillars 370 and the through holes 220 arranged in the base portion 122 as shown in FIGS. 8A and 9A. In some examples, the through holes 220 can be arranged in zones (i.e., one or more regions of the base portion 122) instead of being arranged throughout the base portion 122 as shown in FIGS. 8A and 9A. For example, the zones can be radial, azimuthal, or a combination thereof.

### Showerhead Through Holes

FIGS. 11 and 12 show a bottom view of the showerhead 120 taken along lines C-C shown in FIG. 3. FIGS. 11 and 12 show examples of patterns of the through holes 210 and 220 on the lower surface 204 of the base portion 122. FIG. 11 shows a first pattern of the through holes 210, 220 when the through holes 210, 220 are arranged as described above with reference to FIGS. 8A-8C. FIG. 12 shows a second pattern of the through holes 210, 220 when the through holes 210, 220 are arranged as described above with reference to FIGS. 9A-9C.

Showerhead with Optimized Through Holes

FIGS. 13-16 show an example of a showerhead 121 with through holes of upper and lower plenums optimized to prevent jetting and back diffusion of gases while also allowing to reduce the gap between the showerhead 121 and the substrate 110 (shown in FIG. 1). Specifically, the through holes have conical outlets. Further, the lengths of the through holes, the diameters of the through holes, the lengths of the conical portions of the through holes, and the cone angles of the through holes are optimized as described below in detail. A process gas is supplied through the upper plenum, and an inert gas is supplied through the lower plenum. When the process gas flows out of the showerhead, most molecules tends to travel from the center to the edge or OD of the showerhead (radially outward). Some of the process gas exiting the through holes of the upper plenum can diffuse back into the through holes of the lower plenum. Alternatively, the process gas can be supplied through the lower plenum and the inert gas can be supplied through the upper plenum. In this alternate example, Some of the process gas exiting the through holes of the lower plenum can diffuse back into the through holes of the upper plenum. To prevent the back diffusion, the above-mentioned geometries of the through holes of the upper and lower plenums and the flow rate of the inert gas via the through holes of the lower plenum (or the upper plenum in the alternate example) are optimized such that the process gas neither flows back into the through holes of the lower plenum and also does not cause jetting on the substrate when the gap between the showerhead and the substrate is reduced.

Specifically, the showerhead design allows reduction in the process gas volume by allowing reduction in the gap between the showerhead and the substrate while also preventing jetting on the substrate and back diffusion of the process gas into the showerhead. The showerhead design minimizes the non-uniformity that can be otherwise caused by jetting due to the reduced gap between the showerhead and the substrate. The showerhead design also minimizes particle excursion due to back diffusion of the process gas into the showerhead. As described below in detail, the cone angle and cone height are optimized to minimize the jetting effect. The diameters and the lengths of the through holes are optimized to minimize back diffusion. The flow rate of the inert gas supplied through the lower plenum is optimized to minimize both jetting and back diffusion.

FIG. 13 shows an example of the showerhead 121 with through holes 223, 213 of the upper and lower plenums 202, 200 having conical outlets. The through holes 223 are shown at 223-1, 223-2, . . . , and 223-M (collectively the through holes 223). The through holes 213 are shown at 213-1, 213-2, . . . , and 213-N(collectively the through holes 213). The geometries of the through holes 223, 213 are shown and described below in further detail with reference to FIGS. 15 and 16. The showerhead 121 is similar to the showerhead 120 shown and described above with reference to FIGS. 3-10 except for the differences shown and described with reference to FIGS. 13-16. Accordingly, elements of the showerhead 121 shown using the same reference numerals as those shown and described with reference to FIG. 3 are not described again for brevity. The showerhead 121 can be used in the substrate processing system 100 shown in FIG. 2 instead of the showerhead 120 except that the gap between the showerhead 121 and the substrate 110 can be smaller than the gap between the showerhead 120 and the substrate 110.

In the showerhead 121, unlike the showerhead 120, the through holes 223, 213 of the upper and lower plenums 202, 200 have conical outlets. Further, the lengths, diameters, and cone geometries of the through holes 223, 213 of the upper and lower plenums 202, 200 are different than the cylindrical through holes 220, 210 of the showerhead 120 shown in FIG. 3. Accordingly, the base portion of the showerhead 121 is identified as 123 to distinguish from the base portion 122 of the showerhead 120 shown in FIG. 3. Other than the through holes 223, 213 being different from the through holes 220, 210, other elements of the base portion 123 identified by the same reference numerals as those used to identify and describe the elements of the base portion 122 with reference to FIGS. 3-10 are not described again for brevity. The through holes 213 of the lower plenum 200 are cross-drilled similar to the through holes 210 as shown and described above with reference to FIGS. 3-10. The cross-drilling of the through holes 213 of the lower plenum 200 is therefore not described again for brevity. The through holes 223 of the upper plenum 202 are longer and greater in diameter than the through holes 213 of the lower plenum 200.

FIG. 14 shows an example of a bottom view of the showerhead 121. The through holes 223, 213 of the upper and lower plenums 202, 200 are visible in the view shown. The through holes 223 of the upper plenum 202 are greater in diameter than the through holes 213 of the lower plenum 200.

FIGS. 15 and 16 show examples of the geometries of the through holes 223, 213 of upper and lower plenums 202, 200. FIG. 15 shows an example of the through hole 223 of the upper plenum 202. FIG. 16 shows an example of the through hole 213 of the lower plenum 200.

In FIG. 15, each of the through holes 223 of the upper plenum 202 comprises a stem portion 300 and a conical portion 302. The stem portion 300 is cylindrical. The conical portion 302 extends from the stem portion 300. The stem portion 300 and the conical portion 302 are integral and are not separate elements attached to each other.

The stem portion 300 has a radius r11 and a length L1. The conical portion 302 has a cone length or cone height Lc1. The conical portion 302 has a cone angle q relative to a vertical axis that is parallel to the length L1 of the stem portion 300. An upper end of the conical portion 302 extends from a lower end of the stem portion 300 at the cone angle q. Accordingly, the upper end of the conical portion 302 is of the same diameter as the diameter of the stem portion 300. A lower end of the conical portion 302 has a cone radius r21. The cone radius r21 is greater than the radius r11 of the stem portion 300. The length L1 of the stem portion 300 is greater than the cone length Lc1. The total length or height of the through holes 223 is (L1+Lc1). Examples of dimensions of the stem portion 300 and the conical portion 302 are described below.

In FIG. 16, each of the through holes 213 of the lower plenum 200 comprises a stem portion 310 and a conical portion 312. The stem portion 310 is cylindrical. The conical portion 312 extends from the stem portion 310. The stem portion 310 and the conical portion 312 are integral and are not separate elements attached to each other. The through holes 213 are smaller than the through holes 223.

The stem portion 310 has a radius r12 and a length L2, which are less than the radius r11 and a length L1 of the stem portion 300 of the through holes 223, respectively. The conical portion 312 has a cone length or cone height Lc2, which is less than the cone length Lc1 of the conical portion 302 of the though holes 223. The conical portion 312 has a cone angle φ relative to a vertical axis that is parallel to the length L2 of the stem portion 310. An upper end of the conical portion 312 extends from a lower end of the stem portion 310 at the cone angle q. Accordingly, the upper end of the conical portion 302 is of the same diameter as the diameter of the stem portion 300. The cone angle of the conical portion 312 can be different than the cone angle of the conical portion 302. A lower end of the conical portion 312 has a cone radius r22, which is less than the cone radius r21 of the conical portion 302. The cone radius r22 is greater than the radius r12 of the stem portion 310. The length L2 of the stem portion 310 is greater than the cone length Lc2. The total length or height of the through holes 213 is (L2+Lc2), which is less than the total length (L1+Lc1) of the through holes 223. Examples of dimensions of the stem portion 310 and the conical portion 312 are described below.

To minimize average velocities of the process gas and the inert gas at the conical outlets of the through holes 223, 213 of the upper and lower plenums 202, 200 (i.e., at the lower ends of the conical portions 302, 312), the dimensions of the through holes 223, 213 can be selected as follows. For example, the total length (L1+Lc1) of the through holes 223 of the upper plenum 202 can be 0.5-0.7 inch. The total length (L2+Lc2) of the through holes 213 of the lower plenum 200 can be 0.15-0.35 inch. For example, the diameter of the through holes 223 (i.e., 2 times r11) of the upper plenum 202 can be 0.029-0.039 inch. For example, the diameter of the through holes 213 of the lower plenum 200 (i.e., 2 times r12) can be 0.014-0.018 inch. For example, the cone angle q of the conical portions 302, 312 of the through holes 223, 213 of the upper and lower plenums 202, 200 can be 30, 45, or 60 degrees. Again, the cone angle q of the conical portions 302, 312 of the through holes 223, 213 of the upper and lower plenums 202, 200 can be the same or can be different.

To prevent jetting and back diffusion, in addition to selecting the dimensions of the through holes 223, 213 of the upper and lower plenums 202, 200 as above, the flow rate of the inert gas supplied via the through holes 213 of the lower plenum 200 can be selected based on the dimensions of the through holes 223, 213. For example, when the dimensions of the through holes 223, 213 of the upper and lower plenums 202, 200 are selected according to the above examples, the flow rate of the inert gas supplied via the through holes 213 of the lower plenum 200 can be 300-3200. Alternatively, the process gas can be supplied through the lower plenum 200 and the inert gas can be supplied through the upper plenum 202. In this alternate example, some of the process gas exiting the through holes 213 of the lower plenum 200 can diffuse back into the through holes 223 of the upper plenum 202. In this alternate example, to prevent back diffusion of the process gas into the upper plenum 202, in addition to optimizing and selecting the dimensions of the through holes 223, 213 of the upper and lower plenums 202, 200 according to the above examples, the flow rate of the inert gas supplied via the through holes 223 of the upper plenum 202 can be 300-3200. For example, the controller 160 (shown in FIG. 2) can control the flow rate of the inert gas. If not optimized, higher than the optimized flow rate of the inert gas can increase jetting while lower than the optimized flow rate can increase back diffusion.

All of the optimizations described above have been deduced after extensive experimentation and are not mere design choices. Further, the above optimizations provide the following advantages. Specifically, the combination of optimized geometries of the through holes 223, 213 of the upper and lower plenums 202, 200 and optimized flow rate of the inert gas via the through holes 213 of the lower plenum 200 provides the following advantages: reducing chemistry usage by reducing the gap between the showerhead 121 and the substrate 100, preventing jetting of the process gas on the substrate 110, preventing back diffusion of the process gas into the showerhead, and excursion of contaminants into the upper and lower plenums of the showerhead.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the examples is described above as having certain features, any one or more of those features described with respect to any one of the examples of the disclosure can be implemented in and/or combined with features of any of the other examples, even if that combination is not explicitly described. In other words, the described examples are not mutually exclusive, and permutations of one or more examples with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A dual-plenum showerhead for a substrate processing system comprising:
a base portion comprising a first surface facing a substrate, a second surface opposite the first surface, and a sidewall extending between the first surface and the second surface, the first and second surfaces being flat, and the first and second surfaces and the sidewall defining a first plenum; and
a backplate comprising a shaped surface extending from a center portion of the backplate to a periphery of the backplate, the shaped surface comprising a plurality of portions, at least one of the portions being parallel to the base portion, and at least one of the portions sloping towards the base portion, the periphery of the backplate being attached to the second surface of the base portion defining a second plenum.

2. The dual-plenum showerhead of claim 1 wherein the base portion and the backplate are cylindrical, the dual-plenum showerhead further comprising a plate disposed between the shaped surface and the second surface of the base portion, the plate being of a smaller diameter than the base portion and comprising a plurality of through holes.

3. The dual-plenum showerhead of claim 2 wherein dimensions of the through holes increase along a radius of the plate.

4. The dual-plenum showerhead of claim 2 wherein the through holes are arranged on the plate in concentric circles.

5. The dual-plenum showerhead of claim 4 wherein diameters of the through holes increase with radii of the circles.

6. The dual-plenum showerhead of claim 2 wherein a thickness of the plate is less than a distance between the second surface of the base portion and the center portion of the backplate.

7. The dual-plenum showerhead of claim 2 wherein a thickness of the plate is less than a distance between the second surface of the base portion and at least one of the portions of the shaped surface that is parallel to the base portion and that lies within a radius of the plate.

8. The dual-plenum showerhead of claim 2 wherein a thickness of the plate is less than a distance between the second surface of the base portion and at least one of the portions of the shaped surface that slopes towards the base portion and that lies within a radius of the plate.

9. The dual-plenum showerhead of claim 2 wherein a thickness of the plate is greater than a distance between the second surface of the base portion and at least one of the portions of the shaped surface that is parallel to the base portion and that lies outside a radius of the plate.

10. The dual-plenum showerhead of claim 2 wherein a thickness of the plate is greater than a distance between the second surface of the base portion and at least one of the portions of the shaped surface that slopes towards the base portion and that lies outside a radius of the plate.

11. The dual-plenum showerhead of claim 2 wherein the plate tapers near an outer diameter of the plate.

12. The dual-plenum showerhead of claim 2 wherein the plate is rounded near an outer diameter edge of the plate.

13. The dual-plenum showerhead of claim 2 wherein:
the base portion comprises a first set of through holes extending from the first surface to the first plenum and a second set of through holes extending from the first surface to the second surface;
the first plenum and the first set of through holes are not in fluid communication with the second plenum and the second set of through holes; and
the second plenum, the second set of through holes, and the through holes in the plate are in fluid communication with each other.

14. The dual-plenum showerhead of claim 1 further comprising:
a stem portion attached to the backplate; and
an adapter attached to the stem portion, the adapter comprising a cooling channel disposed in a portion of the adapter to circulate a coolant through the cooling channel.

15. The dual-plenum showerhead of claim 14 wherein the stem portion and the adapter comprise passages that are separately connected to the first and second plenums.

16. The dual-plenum showerhead of claim 15 further comprising a plate disposed between the shaped surface and the second surface of the base portion, the plate being of a smaller diameter than the base portion and comprising a plurality of through holes, wherein:
a first one of the passages is connected to the second plenum through the center portion of the backplate; and
a second one of the passages passes through the center portion of the backplate and a center region of the plate and is connected to the first plenum.

17. The dual-plenum showerhead of claim 16 wherein the first and second one of the passages are coaxial.

18. The dual-plenum showerhead of claim 1 further comprising a heater disposed in the backplate.

19. The dual-plenum showerhead of claim 1 wherein the backplate comprises:
a flat surface opposite the shaped surface;
a second sidewall that extends from the periphery of the backplate towards the flat surface; and
a heater disposed in a groove in the second sidewall at a distal end of the second sidewall.

20. The dual-plenum showerhead of claim 1 wherein the base portion comprises:
bores cross-drilled laterally through the base portion;
a first set of through holes extending from the first surface through bored regions of the base portion to the first plenum; and
a second set of through holes extending from the first surface, through non-bored regions of the base portion, and through the second surface to the second plenum.

21. The dual-plenum showerhead of claim 20 further comprising a ring attached to sidewall of the base portion enclosing the bores.

22. The dual-plenum showerhead of claim 13 wherein the first and second sets of through holes comprise conical ends at the first surface of the base portion.

23. The dual-plenum showerhead of claim 13 wherein the first set of though holes are smaller in length and diameter than the second set of through holes.

24. The dual-plenum showerhead of claim 13 wherein:
the first and second sets of holes comprise a cylindrical portion and a conical portion extending from the cylindrical portion;
the cylindrical portions of the first and second sets of through holes extend to the first and second plenums, respectively; and
the conical portions of the first and second set of through holes extend to the first surface of the base portion.

25. The dual-plenum showerhead of claim 24 wherein the cylindrical and conical portions of the first set of through holes are smaller in length and diameter than the cylindrical and conical portions of the second set of through holes, respectively.

26. The dual-plenum showerhead of claim 24 wherein:
the cylindrical portions of the first set of through holes are smaller in length and diameter than the cylindrical portions of the second set of through holes; and
the conical portions of the first set of through holes are smaller in length and diameter than the conical portions of the second set of through holes.

27. The dual-plenum showerhead of claim 24 wherein:
the conical portions of the first set of through holes extend at a first angle relative to an axis parallel to a length of the cylindrical portions of the first set of through holes; and
the conical portions of the second set of through holes extend at a second angle relative to an axis parallel to a length of the cylindrical portions of the second set of through holes.

28. The dual-plenum showerhead of claim 27 wherein the first and second angles are equal.

29. A system comprising the showerhead of claim 22 and further comprising:
a first gas source configured to supply a first gas to the first plenum;
a second gas source configured to supply a second gas to the second plenum; and
a controller configured to control a flow rate of the first gas at a flow rate selected to reduce jetting of the second gas through the second set of through holes and to reduce the second gas from diffusing into the first plenum via the first set of through holes.

30. A system comprising the showerhead of claim 26 and further comprising:
a first gas source configured to supply a first gas to the first plenum;
a second gas source configured to supply a second gas to the second plenum; and
a controller configured to control a flow rate of the first gas at a flow rate selected to reduce jetting of the second gas through the second set of through holes and to reduce the second gas from diffusing into the first plenum via the first set of through holes.

31. A system comprising the showerhead of claim 22 and further comprising:
a first gas source configured to supply a first gas to the first plenum;
a second gas source configured to supply a second gas to the second plenum; and
a controller configured to control a flow rate of the second gas at a flow rate selected to reduce jetting of the first gas through the first set of through holes and to reduce the first gas from diffusing into the second plenum via the second set of through holes.

32. A system comprising the showerhead of claim 26 and further comprising:
a first gas source configured to supply a first gas to the first plenum;
a second gas source configured to supply a second gas to the second plenum; and
a controller configured to control a flow rate of the second gas at a flow rate selected to reduce jetting of the first gas through the first set of through holes and to reduce the first gas from diffusing into the second plenum via the second set of through holes.

33. The showerhead of claim 24 wherein a total length of the first set of through holes is in a range of 0.15-0.35 inch, and wherein a total length of the second set of through holes is in a range of 0.5-0.7 inch.

34. The showerhead of claim 24 wherein a diameter of the cylindrical portions of the first set of through holes is in a range of 0.014-0.018 inch and wherein a diameter of the cylindrical portions of the second set of through holes is in a range of 0.029-0.039 inch.

35. The showerhead of claim 24 wherein the conical portions of the first and second sets of through holes extend at an angle in a range of 30-60 degrees relative to an axis parallel to lengths of the cylindrical portions of the first and second sets of through holes.
